(19) United States
(12) Patent Application Publication
(10) Pub. No.: US 2012/0171556 A1
(43) Pub. Date: Jul. 5, 2012

(54) SECONDARY BATTERY

(76) Inventors: Jongpil Kim, Yongin-si (KR); Daegeun Kim, Yongin-si (KR); Sungil Lim, Yongin-si (KR)

(21) Appl. No.: 13/161,437

(22) Filed: Jun. 15, 2011

Related U.S. Application Data
(60) Provisional application No. 61/428,218, filed on Dec. 29, 2010.

(51) Int. Cl. H01M 2/02; H05K 3/30; H01M 2/06

(52) U.S. Cl. 429/174; 29/832

(57) ABSTRACT

A secondary battery including an electrode assembly; a can housing the electrode assembly; a cap assembly sealing the can; an upper case covering the cap assembly; and a protective circuit module between the cap assembly and the upper case, the protective circuit module having a printed circuit board; and a first protective circuit device coupled to the printed circuit board by a first solder; and an external terminal electrically coupled to the printed circuit board by a second solder, wherein a melting point of the first solder is not lower than a melting of the second solder.

### CROSS-REFERENCE TO RELATED APPLICATIONS

This application claims priority to and the benefit of U.S. Provisional Application No. 61/428,218, filed on Dec. 29, 2010, in the United States Patent and Trademark Office, the disclosure of which is incorporated herein in its entirety by reference.

### BACKGROUND

1. Field

Aspects of the present invention relate to a secondary battery.

2. Description of the Related Art

A secondary battery generally includes an external terminal formed at its upper case for being electrically connected with an external device. The external terminal is electrically connected with a protective circuit module(PCM) electrically connected with an upper portion of the bare cell. In addition, an electrical connection between the external terminal and the PCM can be performed by manually, soldering the external terminal on the protective circuit board (PCB) of the PCM.

### SUMMARY

Aspects of the present invention provide a secondary battery having improved quality and manufactured in a simplified manner by automating a soldering process required to electrically connect an external terminal provided at an upper case of the secondary battery with a PCM.

According to one embodiment, a secondary battery includes an electrode assembly; a can housing the electrode assembly; a cap assembly sealing the can; an upper case covering the cap assembly; and a protective circuit module between the cap assembly and the upper case, the protective circuit module including a printed circuit board; and a first protective circuit device coupled to the printed circuit board by a first solder; and an external terminal electrically coupled to the printed circuit board by a second solder, wherein a melting point of the first solder is not lower than a melting of the second solder.

In embodiments, the second solder comprises an alloy of tin and bismuth, wherein the second solder is at least about 45% bismuth and wherein a melting point of the second solder is about 138 ° C. In one embodiment, a melting point of the second solder is lower than a softening point of the upper case.

Additionally, in one embodiment, the upper case is made of a resin including about 50% to about 60% glass fiber and wherein a softening point of the upper case is about 170° C.

In one embodiment, the first solder is on an exterior-facing surface of the protective circuit board, wherein the second solder is on an interior-facing surface of the protective circuit board, and wherein the melting point of the first solder is greater than the melting point of the second solder. Additionally, the secondary battery may include a second protective circuit device on the interior-facing surface of the printed circuit board, wherein the second protective circuit device is coupled to the printed circuit board by a third solder. In one embodiment, the melting point of the second solder and a melting point of the third solder are the same and the second solder and the third solder are made of the same material.

In one embodiment, the first solder and the second solder are on an interior-facing surface of the protective circuit board and the melting point of the first solder and the second solder are the same.

The upper case may have a first support, wherein a first lead plate is coupled to the first support and is electrically coupled to the protective circuit board and to the cap assembly. Additionally, the external terminal may be coupled to the second solder by a welding lead through the protective circuit board.

In another embodiment of the present invention, a method of manufacturing a second battery is provided, the method including soldering a first protective device onto a printed circuit board using a first solder to electrically couple the first protective device to the printed circuit board; soldering an external terminal located on an outer case to the printed circuit board using a second solder to electrically couple the external terminal to the printed circuit board, wherein the second solder is made from a different material than the first solder; coupling the outer case and the printed circuit board to a cap plate of a bare cell also comprising an electrode assembly and a can, wherein the cap plate seals the can, wherein the printed circuit board is between the bare cell and the outer case, and wherein the external terminal is exposed through the outer case.

In one embodiment, the soldering of the first protective device is performed at a higher temperature than the soldering of the external terminal and may be performed by reflow soldering. Additionally, the method may also include soldering a second protective device to the printed circuit board by using a third solder, wherein the second solder and the third solder comprise the same material.

In the secondary battery according to embodiments of the present invention, since a soldering process for electrically connecting an external terminal with a PCM is automated, a cleaning process for removing soldering debris can be omitted, thereby simplifying the fabrication process and saving a processing labor force.

Also, in the secondary battery according to the embodiment of the present invention, the automated soldering process can prevent the bare cell and the PCM from being electrically shorted due to a difference in between solder heights and can reduce a deviation in the performance between processing workers.

### BRIEF DESCRIPTION OF THE DRAWINGS

FIG. 1 is an exploded perspective view of a secondary battery according to an embodiment of the present invention;

FIG. 2 is a sectional view illustrating an upper case of a secondary battery according to an embodiment of the present invention and a PCM coupled to each other, taken along the line X-X′ of FIG. 1; and

FIG. 3 is a sectional view illustrating that an upper case of a secondary battery according to another embodiment of the present invention and a PCM are coupled to each other.

### DETAILED DESCRIPTION

Hereinafter, embodiments of the present invention will be described in detail with reference to the accompanying drawings.

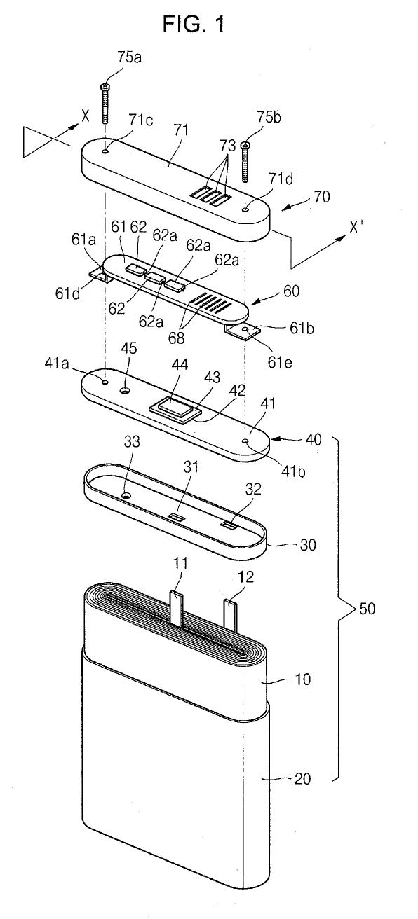

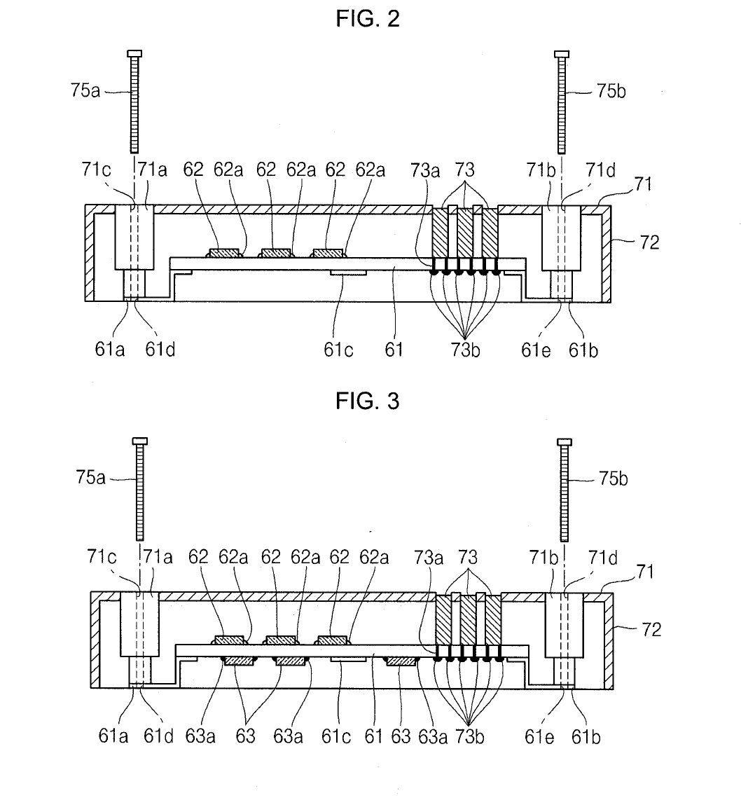

FIG. 1 is an exploded perspective view of a secondary battery according to an embodiment of the present invention, and FIG. 2 is a sectional view illustrating an upper case of a secondary battery according to an embodiment of the present invention and a PCM coupled to each other, taken along the line X-X′ of FIG. 1.

Referring to FIG. 1, the secondary battery according to the illustrated embodiment of the present invention includes a bare cell 50, a PCM 60 formed on the bare cell 50 and electrically connected to the bare cell 50, and an upper case 70 fixed to the bare cell 50 while covering the PCM 60. Here, the bare cell 50 includes an electrode assembly 10, a can 20 housing the electrode assembly 10 therein, an insulation case 30 inserted into the can 20 through an upper opening of the can 20, and a cap assembly 40 formed on the insulation case 30 and electrically connected to the electrode assembly 10.

The electrode assembly 10 includes a negative electrode plate, a positive electrode plate, and a separator. The negative electrode plate and the positive electrode plate are stacked with the separator located therebetween, and are wound in a jelly-roll configuration. A negative electrode tab 11 is welded to the negative electrode plate, and one end of the negative electrode tab 11 protrudes toward an upper portion of the electrode assembly 10. In addition, a positive electrode tab 12 is welded to the positive electrode plate and one end of the positive electrode tab 12 protrudes toward an upper portion of the electrode assembly 10. It would be appreciated by those skilled in the art that polarities of the negative electrode tab 11 and the positive electrode tab 12 may be reversed.

The can 20 may be formed of a metal member having a substantially cuboidal shape. In addition, the can 20 has an open top forming a top opening, wherein the electrode assembly 10 is received through the top opening. In some cases, the can 20 may be used as an electrode terminal and may generally have a polarity opposite to an electrode terminal 44 to be described later. As described above, since the polarities of the negative electrode tab 11 and the positive electrode tab 12 may be reversed, the electrode terminal 44 may be either a negative electrode terminal or a positive electrode terminal. In addition, when the electrode terminal 44 is a positive electrode terminal, the polarity of the can 20 may be negative, and when the electrode terminal 44 is a negative electrode terminal, the polarity of the can 20 may be positive. The detailed description of embodiments of the present invention will be made based on the assumption that the polarity of the can 20 is positive and the electrode terminal 44 is negative electrode terminal.

The insulation case 30 includes a negative electrode tab hole 31 at a location generally corresponding to the negative electrode tab 11 to have a size and a shape generally corresponding to the negative electrode tab 11, and a positive electrode tab hole 32 at a location generally corresponding to the positive electrode tab 12 to have a size and a shape generally corresponding to the positive electrode tab 12. In addition, the insulation case 30 includes an electrolyte hole 33 formed at one side to allow an electrolytic solution pass therethrough.

The insulation case 30 is shaped to correspond to the top opening of the can 20 and is inserted into the top opening to then be coupled to the can 20. In addition, the insulation case 30 insulates the electrode assembly 10 from the cap assembly 40. Thus, the insulation case 30 is made of an electrically insulating material.

The cap assembly 40 includes a cap plate 41, an electrode terminal 44 inserted into the electrode terminal hole 42 extending through the center of the cap plate 41, and an insulation gasket 43 located between the electrode terminal hole 42 and the electrode terminal 44. The cap plate 41 includes a first thread groove 41a and a second thread groove 41b formed lengthwise at one and the other sides of the cap plate 41. In addition, the cap plate 41 includes an electrolyte injection hole 45 at a location generally corresponding to the electrolyte hole 33 and having a size and a shape generally corresponding to the electrolyte hole 33.

The cap plate 41 may be formed of a metal plate shaped to generally correspond to the top opening of the can 20 and having a size and a shape generally corresponding to the insulation case 30. The positive electrode tab 12 is coupled to the bottom surface of the cap plate 41 by welding, thereby allowing the positive electrode of the electrode assembly 10 and the cap plate 41 to be electrically connected. In addition, the cap plate 41 serves to seal the top opening of the can 20.

The negative electrode tab 11 is coupled to the bottom surface of the electrode terminal 44 by welding, thereby allowing the negative electrode of the electrode assembly 10 and the electrode terminal 44 to be electrically connected.

As described above, the insulation gasket 43 is located between the electrode terminal hole 42 and the electrode terminal 44, thereby electrically insulating the cap plate 41 and the electrode terminal 44 from each other.

Configurations of the PCM 60 and the upper case 70 of the secondary battery according to the illustrated embodiment, and a structure in which the PCM 60 and the upper case 70 are coupled to each other, will now be described.

The PCM 60 includes a printed circuit board (PCB) 61, first and second lead plates 61a and 61b attached to ends of either side of the bottom surface of the PCB 61, and a terminal plate 61c attached to the center of the bottom surface of the PCB 61. In addition, the PCM 60 includes a first protective circuit device 62 coupled to the PCB 61 by soldering using a first solder 62a coated on a top surface of the PCB 61. The protective circuit device acts to generally control charging and discharging of the secondary battery. In addition, an insertion hole 68, into which an external terminal 73 to be described later is inserted, is formed at the other side of the PCB 61.

A conductive wire pattern is mounted on the PCB 61 so that components, such as protective circuit devices or lead plates, which are attached to the top or bottom surface of the PCB 61, may be electrically connected.

The first lead plate 61a includes a first thread hole 61d at a location generally corresponding to the first thread groove 41a and having a size and a shape generally corresponding to the first thread groove 41a.

The first lead plate 61a is coupled to a first support 71a formed in the upper case 70 and the top surface of the cap plate 41, thereby allowing the PCM 60 to be coupled to the upper case 70 and the bare cell 50.

The second lead plate 61b includes a second thread hole 61e at a location generally corresponding to the second thread groove 41b and having a size and a shape generally corresponding to the second thread groove 41b. The second lead plate 61b is coupled to a second support 71b formed in the upper case 70 and the top surface of the cap plate 41, thereby allowing the PCM 60 to be coupled to the upper case 70 and the bare cell 50. In addition, the second lead plate 61b is electrically connected to the conductive wire pattern.

The terminal plate 61c is electrically connected to the conductive wire pattern. In addition, the terminal plate 61c is coupled to the electrode terminal 44 when the PCM 60 is combined with the bare cell 50, thereby electrically connecting the negative electrode of the electrode assembly 20 to the PCM 60.

The protective circuit device 62 is electrically connected to the conductive wire pattern and controls charge/discharge operations, thereby protecting the secondary battery. Although FIG. 2 shows that as a result of coupling, the PCM 60 (i.e., three first protective circuit devices 62 mounted on a top surface of the PCB 61), is coupled to the upper case 70, the present invention is not limited to the number of the first protective circuit devices 62 shown.

The first solder 62a is made of an alloy of tin (Sn), silver (Ag) and copper (Cu). In one embodiment, a composition of the alloy includes about 96.5% of Sn, about 3.0% of Ag, and about 0.5% of Cu. In this case, since a melting point of the first solder 62a is about 220° C., the first soldering is performed at about 220° C. or higher. The first soldering may be either flow soldering or reflow soldering. If the first soldering is based on the reflow soldering, the reflow conditions may include a peak temperature of between about 250° C. and about 255° C. and a peak time of about 30 to 70 seconds.

The flow soldering is performed such that solder is melted and placed in a solder-pot, the solder is waved, and the waved solder is allowed to pass through a PCB having components mounted thereon by transferring the PCB through a conveyor. The reflow soldering, commonly called surface mount technology (SMT) as well, is performed such that cream solder is printed on a PCB, components are attached to the PCB, and the PCB having the components is allowed to pass through a reflow soldering machine. In this case, the reflow soldering machine performs soldering by melting cream solder.

The upper case 70 includes a lid 71 covering the PCM 60 and the cap assembly 40, and a sidewall 72 extending from an edge of the lid 71 of the upper case toward the can 20. In addition, a first support 71a and a second support 71b are formed at either side of the lid 71 extending generally toward the can 20. The first support 71a includes a third thread hole 71c at a location generally corresponding to the first thread hole 61d to have a size and a shape generally corresponding to the first thread hole 61d. In addition, the second support 71b includes a fourth thread hole 71d at a location generally corresponding to the second thread hole 61e to have a size and a shape generally corresponding to the second thread hole 61e. Further, the lid 71 includes an external terminal 73 at a location generally corresponding to the insertion hole 68 formed in the PCB 61, and a welding lead 73a is formed on a bottom surface of the external terminal 73.

The upper case 70 is shaped and sized to generally correspond to openings of the cap plate 41 and the can 20. The upper case 70 is made of a resin comprising glass fiber added in the range of about 50% to about 60%. In one embodiment, a softening point (i.e., a temperature at which a solid material starts to deform by being heated) of the upper case 70 is 170° C. or higher.

If the resin includes less than 50% of glass fiber, the softening point is low enough so that the upper case 70 may deform when soldering, specifically second soldering, is performed on the welding lead 73a. If the resin includes more than 60% of glass fiber, the upper case 70 may be difficult to form.

In the above stated range of glass fiber, a mold shrinkage (in a generally perpendicular direction) of the upper case 70 is in a range of between about 0.5 and about 1, and in one embodiment is about 0.7.

The first support 71a is combined with the first lead plate 61a constituting the PCM 60 by a first thread 75a, thereby fixing the PCM 60 to the upper case 70. The second support 71b is combined with the second lead plate 61b constituting the PCM 60 by a second thread 75b, thereby fixing the PCM 60 to the upper case 70.

The external terminal 73 is electrically connected to the PCB 61 such that the welding lead 73a formed on the bottom surface of the external terminal 73 is inserted into an insertion hole 68 extending through the PCB 61, to then be subjected to soldering, specifically second soldering using the second solder 73b coated on the bottom surface of the PCB 61.

The second solder 73b and the first solder 62a may be made of different materials. In one embodiment, the second solder 73b is made of an alloy of tin (Sn) and bismuth (Bi). When alloyed with other metals, Bi melts at a temperature lower than its own melting point, i.e., 271° C.

The alloy of the second solder 73b comprises about 45% of Bi or greater, and in one embodiment, about 58%. In this case, a melting point of the second solder , 73b is about 138° C. Therefore, the second soldering for melting the second solder 73b is performed at about 138° C. or higher.

In one embodiment, the second soldering is performed at a temperature lower than the softening point of the upper case 70 and the melting point of the first solder 62a, i.e., at a temperature lower than 170° C. More specifically, in one embodiment, the temperature for performing the second soldering is higher than 138° C. and lower than 170° C., for example at a temperature in a range of about 150° C. to about 160° C.

In one embodiment, the second soldering is based on the reflow soldering. After components are mounted on a top surface of the PCB 61, cream solder is coated on a bottom surface of the PCB 61 to then be combined with the upper case 70, followed by passing through a reflow machine, thereby achieving processing automation. If the second soldering is based on the reflow soldering, the reflow conditions may include a peak temperature of between about 150° C. and about 165° C. and a peak time of about 30 to 100 seconds. In other words, even if the second soldering is based on the reflow soldering, the melting point of the first solder 62a is higher than a temperature at which the second soldering is performed. Thus, the first solder 62a will not significantly melt during the second soldering.

As described above, after the PCM 60 is combined with the upper case 70, the first lead plate 61a and the second lead plate 61b are coupled to the cap plate 41, respectively, thereby combining the PCM 60 with the bare cell 50. In one embodiment, the combining between the PCM 60 and the bare cell 50 is achieved by tightening the first thread 75a and the second thread 75b with the first thread groove 41a and the second thread groove 41b provided on the cap plate 41.

In such a manner, the secondary battery according to the illustrated embodiment of the present invention is completed by first combining the PCM 60 with the upper case 70 and then combining the upper case 70 with the bare cell 50. In addition, the secondary battery according to the illustrated embodiment of the present invention is manufactured such that a temperature of the second soldering is lower than the first soldering. Accordingly, the operation of combining the PCM 60 with the upper case 70 is achieved through one cycle of reflow processing, thereby increasing the manufacturing efficiency.

Next, a secondary battery according to another embodiment of the present invention will be described.

FIG. 3 is a sectional view illustrating an upper case of a secondary battery according to another embodiment of the present invention and a PCM coupled to each other.

Referring to FIG. 3, the secondary battery according to the illustrated embodiment of the present invention is substantially the same as the secondary battery according to the previous embodiment in view of configuration and operation, except that a second protective circuit device 63 and a third solder 63a are further formed on the bottom surface of a PCB 61. Thus, the following description will focus on primarily the differences between the secondary batteries according to the illustrated embodiment and the previous embodiment of the present invention, and repetitive descriptions will not be given.

A second protective circuit device 63 formed on a bottom surface of the PCB 61 is subjected to soldering, specifically third soldering, using a third solder 63a coated on the bottom surface of the PCB 61, thereby combining the second protective circuit device 63 with the bottom surface of the PCB 61. While FIG. 3 illustrates that each three protective circuit devices are mounted on top and bottom surfaces of the PCB 61, which is provided only by way of example, the invention does not limit the number or location of protective circuit devices to the illustrated example.

In one embodiment, the third solder 63a and the first solder 62a are made of different materials and the third solder 63a and the second solder 73b are made of the same material. More specifically, the third solder 63a is made of an alloy of Sn and Bi. Therefore, the alloy of the third solder 63a comprises about 45% of Bi or higher, and in one embodiment, about 58%.

In this case, a melting point of the third solder 63a is about 138° C. Therefore, the third soldering for melting the third solder 63a is performed at about 138° C. or higher.

In addition, in one embodiment the third soldering is performed at a temperature lower than the softening point of the upper case 70 and the melting point of the first solder 62a. Therefore, the third soldering should be performed at a temperature lower than 170° C. In one embodiment, the temperature for performing the third soldering is higher than 138° C. and lower than 170° C., and more specifically at a temperature in a range of about 150° C. to about 160° C.

In one embodiment, the third soldering is based on reflow soldering. Cream solder is coated on a bottom surface of the PCB 61, components are mounted on a bottom surface of the PCB 61, and the PCB 61 is then combined with the upper case 70. In such a state, the resultant structure is allowed to pass through a reflow machine all at once, thereby achieving processing automation. Thus, the second soldering and the third soldering are performed at the same time. Accordingly, even if the third soldering is based on the reflow soldering, the melting point of the first solder 62a is higher than a temperature at which the third soldering is performed. Thus, the first solder 62a will not significantly melt during the third soldering.

The embodiment shown in FIG. 3 is directed to additional components mounted on the bottom surface of PCB 61 after mounting the components on the top surface of the PCB 61 through the first soldering. After all the components are mounted on the bottom surface of the PCB 61 without mounting components to the top surface of the PCB 61, the welding lead 73a formed on the bottom surface of the external terminal 73 may be connected to the PCB 61 and an assembly of the PCB 61 and upper case 70 may then be passed through a reflow machine all at once to assemble the components and couple the terminals to each other.

A method of manufacturing a secondary battery according to an embodiment of the present invention will now be described.

The method of manufacturing the secondary battery according to the exemplary embodiment of the present invention includes (S1) mounting a first protective circuit device 62, (S2) performing a first soldering, (S3) combining a PCB 61 and an upper case 70, (S4) performing a second soldering, (S5) coupling the upper case 70 to a bare cell 50.

In step 51, a first solder 62a is coated on a position of a top surface of the PCB 61, where the first protective circuit device 62 is to be mounted, and the first protective circuit device 62 is inserted into the to-be-mounted position.

In step S2, the first soldering is performed using the first solder 62a, thereby fixing the first protective circuit device 62 on the top surface of the PCB 61 and electrically connecting the first protective circuit device 62 and the PCB 61 to each other.

In step S3, a second solder 73b is coated on a portion of a bottom surface of the PCB 61, where an insertion hole 68 is formed, and a welding lead 73a formed on a bottom surface of an external terminal 73 of the upper case 70 is inserted into the insertion hole 68. As described above, in one embodiment the second solder 73b has a lower melting point than the first solder 62a.

In step S4, the second soldering is performed using the second solder 73b to fix the external terminal 73 to the PCB 61 through the welding lead 73a. In addition, as the result of performing the second soldering (i.e., step S5), the external terminal 73 and the PCB 61 are electrically connected to each other. In one embodiment, a temperature for performing the second soldering is lower than a temperature for performing the first soldering, and the second soldering is based on reflow soldering.

In step S5, the upper case 70 combined with the PCB 61 is coupled to the cap plate 41 forming the bare cell 50. Here, the coupling is achieved by screw tightening using a first screw 75a and a second screw 75b.

Next, a method of manufacturing a secondary battery according to another embodiment of the present invention will be described. The manufacturing method of the secondary battery according to the illustrated embodiment of the present invention is substantially the same as the manufacturing method of the secondary battery according to the previous embodiment, except that it further includes (S21) mounting a second protective circuit device 63. Thus repetitive descriptions thereof will not be given.

Step S21 is performed between step S2 and S3. In S21, the third solder 63a is coated on a position where the second protective circuit device 63 is to be mounted, and the second protective circuit device 63 is then inserted into the to-be-mounted position. As described above, in one embodiment, a melting point of the third solder 63a is lower than that of the first solder 62a and the third solder 63a is soldered at the same time when performing second soldering using the second solder 73b.

As described above, the secondary battery according to the embodiment of the present invention can effectively simplify the fabrication process and save a processing labor force by automating the soldering process for electrically connecting the external terminal with the PCM, by which the cleaning process for removing soldering debris can be omitted.

Also, in the secondary battery according to the embodiment of the present invention, the automated soldering process can prevent the bare cell and the PCM from being electrically shorted due to a difference between solder heights and can reduce a deviation in the performance between processing workers.

While this invention has been particularly shown and described with reference to preferred embodiments thereof, it will be understood by those skilled in the art that various changes in form and details may be made therein without departing from the spirit and scope of the invention.

DESCRIPTION OF THE SYMBOLS IN THE DRAWINGS

| | |
|---|---|
| 10: Electrode assembly | 11: Negative electrode tab |
| 12: Positive electrode tab | 20: Can |
| 30: Insulation case | 31: Negative electrode tab hole |
| 32: Positive electrode tab hole | 33: Electrolyte hole |
| 40: Cap assembly | 41: Cap plate |
| 42: Electrode terminal hole | 43: Insulation gasket |
| 44: Electrode terminal | 45: Electrolyte injection hole |
| 50: Bare cell | 60: protective circuit |
| | module(PCM) |
| 61: protective circuit board(PCB) | 61a: First lead plate |
| 61b: Second lead plate | 61c: Terminal plate |
| 62: First protective circuit device | 62a: First solder |
| 63: Second protective circuit device | 63a: Third solder |
| 68: External terminal insertion hole | 70: Upper case |
| 71: Lid | |
| 71a: First support | 71b: Second support |
| 72: Sidewall | |
| 73: External terminal | 73a: Welding lead |
| 73b: Second solder | |

What is claimed is:

1. A secondary battery comprising:
an electrode assembly;
a can housing the electrode assembly;
a cap assembly sealing the can;
an upper case covering the cap assembly; and
a protective circuit module between the cap assembly and the upper case, the protective circuit module comprising:
a printed circuit board; and
a first protective circuit device coupled to the printed circuit board by a first solder; and
an external terminal electrically coupled to the printed circuit board by a second solder, wherein a melting point of the first solder is not lower than a melting point of the second solder.

2. The secondary battery of claim 1, wherein the second solder comprises an alloy of tin and bismuth.

3. The secondary battery of claim 2, wherein the second solder comprises at least about 45% bismuth.

4. The secondary battery of claim 1, wherein a melting point of the second solder is about 138 ° C.

5. The secondary battery of claim 1, wherein a melting point of the second solder is lower than a softening point of the upper case.

6. The secondary battery of claim 1, wherein the upper case comprises a resin comprising about 50% to about 60% glass fiber.

7. The secondary battery of claim 1, wherein a softening point of the upper case is about 170° C.

8. The secondary battery of claim 1, wherein the first solder is on an exterior-facing surface of the protective circuit board, wherein the second solder is on an interior-facing surface of the protective circuit board, and wherein the melting point of the first solder is greater than the melting point of the second solder.

9. The secondary battery of claim 8, further comprising a second protective circuit device on the interior-facing surface of the printed circuit board, wherein the second protective circuit device is coupled to the printed circuit board by a third solder.

10. The secondary battery of claim 9, wherein the melting point of the second solder and a melting point of the third solder are the same.

11. The secondary battery of claim 9, wherein the second solder and the third solder comprise the same material.

12. The secondary battery of claim 1, wherein the first solder and the second solder are on an interior-facing surface of the protective circuit board and wherein the melting point of the first solder and the second solder are the same.

13. The secondary battery of claim 1, wherein the upper case has a first support and wherein a first lead plate is coupled to the first support and is electrically coupled to the protective circuit board and to the cap assembly.

14. The secondary battery of claim 1, wherein the external terminal is coupled to the second solder by a welding lead through the protective circuit board.

15. A method of manufacturing a second battery, the method comprising:
soldering a first protective device onto a printed circuit board using a first solder to electrically couple the first protective device to the printed circuit board;
soldering an external terminal located on an outer case to the printed circuit board using a second solder to electrically couple the external terminal to the printed circuit board, wherein the second solder comprises a different material than the first solder;
coupling the outer case and the printed circuit board to a cap plate of a bare cell also comprising an electrode assembly and a can, wherein the cap plate seals the can, wherein the printed circuit board is between the bare cell and the outer case, and wherein the external terminal is exposed through the outer case.

16. The method of claim 15, wherein the soldering of the first protective device is performed at a higher temperature than the soldering of the external terminal.

17. The method of claim 15, wherein the soldering the external terminal is performed by reflow soldering.

18. The method of claim 15, further comprising soldering a second protective device to the printed circuit board by using a third solder, wherein the second solder and the third solder comprise the same material.

19. The method of claim 18, wherein the first protective device and the second protective device are located on opposite sides of the printed circuit board.
